(19) United States
(12) Patent Application Publication
(10) Pub. No.: US 2019/0074817 A1
(43) Pub. Date: Mar. 7, 2019

(54) BAW RESONATOR LESS PRONE TO SPURIOUS MODES, BAW FILTER, AND MANUFACTURING METHOD

(71) Applicant: SNAPTRACK, INC., San Diego, CA (US)

(72) Inventor: Gregory CARUYER, San Diego, CA (US)

(21) Appl. No.: 16/080,616

(22) PCT Filed: Mar. 3, 2017
(86) PCT No.: PCT/IB2017/051266

§ 371 Date: Aug. 28, 2018

(30) Foreign Application Priority Data
Mar. 4, 2016 (DE) 102016103959.4

(51) Int. Cl. H03H 9/17; H03H 9/54; H03H 3/02; C23C 16/44; H03H 9/02

(52) U.S. Cl. CPC H03H 9/171; H03H 9/54; H03H 9/02086; C23C 16/44; H03H 3/02

(57) ABSTRACT

A BAW resonator that is less prone to spurious modes comprises a bottom electrode, a top electrode, a bottom piezoelectric layer between the electrodes, a top piezoelectric layer between the bottom piezoelectric layer and the top electrode, and a conductive layer between the two piezoelectric layers.

The present invention relates to BAW resonators (BAW=bulk acoustic wave) that have reduced spurious modes and may be used in HF filters.

BAW resonators have a sandwich design with two electrodes and a piezoelectric material between the electrodes. If an HF signal of a suitable frequency is applied to the electrodes, due to the piezoelectric effect the construction resonates while the piezoelectric material transduces electrical oscillations into acoustic oscillations, and vice versa. The sandwich design has a layer stack, and the thickness of the layers and the materials of the layers determine the characteristic frequency of the stack. A resonance is achieved in the event that the characteristic frequency coincides with the externally applied HF frequency. If such resonators are electrically interconnected, for example in a conductor-like configuration, HF filters may then be formed, for example bandpass filters or band-stop filters. HF filters that comprise BAW resonators may have a good output stability per area that is required for the resonators. Such HF filters are thus well suited for use in wireless communication devices.

However, in addition to the resonances required for the filtering functionality, unwanted oscillation modes (also known as spurious modes) are excited in conventional BAW resonators. Spurious modes cause rippling in the passband or stop band of the filter, which reduces the quality factor Q of the resonators, which leads to losses in the corresponding filters.

One means of reducing the spurious modes is a frame-like structure that is arranged on the topmost electrode, for example as known from the U.S. Pat. No. 6,812,619 or from the article “Improved Modelling of Bulk Acoustic Wave Resonators and Filters” (A. Hagelauer et al., in the Proceedings of the 2010 IEEE International Ultrasonics Symposium). Furthermore, such resonators require a larger area, which is undesirable due to the present development in the direction of miniaturization.

What is thus needed is a resonator that has improved electroacoustic properties without the requirement of additional area.

Such a resonator, a corresponding filter and a method for manufacturing such resonators are provided by the claims. Dependent claims offer preferred embodiments.

A resonator with reduced spurious modes comprises a bottom electrode and a top electrode. The resonator also comprises a bottom piezoelectric layer that is arranged between the bottom electrode and the top electrode. The resonator also comprises a top piezoelectric layer that is arranged between the bottom piezoelectric layer and the top electrode. In addition to this, the resonator has a conductive layer that is arranged between the bottom piezoelectric layer and the top piezoelectric layer. The conductive layer is electrically floating. The bottom electrode and the top electrode may be used in order to electrically connect the resonator with an external circuit environment, for example of an RF filter. The bottom electrode and the top electrode receive the external electrical signal, and the piezoelectric material between the bottom electrode and the top electrode transduces between electrical and acoustic signals. The electrical potential of the bottom electrode and of the top electrode is thus determined.

In contrast to this, the conductive layer is floating, which means that the conductive layer is electrically connected with neither the bottom electrode, nor the top electrode, nor another external electrical potential.

The bottom electrode, the top electrode and the conductive layer comprise an electrically conductive material which may be different for the different electrode layers or conductive layers.

The layer stack of the present resonator thus has a conductive material between the electrodes, which aids in forming the geometric alignment of the corresponding electrical field between the two electrodes. It has been established that the alignment of the electrical field in the border region of a resonator, in particular horizontally aligned electrical field components, contribute [sic] to the excitation of spurious modes. Since the conductive material of the conductive layer is arranged between the two electrodes, the alignment of the electrical field is improved in the border region of the resonator; in particular, horizontally aligned field components are reduced.

Vertically aligned components of the electrical field, meaning in a direction orthogonal to the surface of an electrode, contribute to the formation of the desired oscillation mode, which is typically a longitudinal mode known as a TE mode (Thickness Extensional Wave Mode). Electrical field components that are arranged horizontally, meaning within the plane defined by the electrodes, may cause the piezoelectric material to deform in a horizontal direction, which leads to spurious modes.

The presence of the conductive material of the conductive layer, at least in the border region of the resonator, aids in reducing such unwanted excursions, and thus reduces spurious modes.

The active region of a resonator is defined as the overlap region, in which the bottom electrode and the top electrode primarily overlap with the piezoelectric material between the electrodes. The border region of the resonator is the edge region of the active region, and in most instances is determined by the borders of the corresponding electrodes.

The conductive material of the conductive layer is required in the border region of the resonator. It is thus possible that the material of the conductive layer is located only in the edge region of the resonator. However, such a configuration exhibits a reduced symmetry, and diffraction effects of sound waves that propagate in the resonator may artificially reduce the electroacoustic properties of the resonator. It may thus be preferred if the material of the conductive layer is homogeneously distributed in both the border region of the resonator and the inner sections of the resonator. The material of the conductive layer may thus be provided as a homogeneous metallization in the entire active region of the resonator.

The size of the electrodes determines the size of the active region. The size of the electrodes is limited to the position of the resonator. In the event that multiple resonators that are needed to form an HF filter are arranged in parallel, the electrodes of the corresponding resonators generally may not be directly connected in order to prevent short circuits.

In contrast to this, the piezoelectric material between the electrodes has a sufficiently low conductivity and cannot short other resonators. In order to simplify manufacturing steps, multiple resonators may share the same piezoelectric material. However, in order to ensure the floating behavior of the conductive layer, the conductive layers of different resonators may not be electrically connected. However, in order to increase the homogeneity of the layer construction in the active region, the material of the conductive layer may extend beyond the area of the resonator, for example the active region of the resonator that is determined by the electrodes.

The acoustics of the resonator are then less disrupted, and the electrical effect of the conductive layer on the electrical field distribution is improved.

In particular if the area of the material of the conductive layer is greater than the area of the electrodes, the electrical effects that occur in the border region of the resonator are decoupled from the acoustic effects that occur in the border region, which leads to improved electroacoustic effects. The separation between the electrical effects and the acoustic effects also enables the effects to be handled individually. An additional frame structure, having an acoustic influence but no electrical influence, over the top electrode may thus contribute more effectively to the improvement of the response of the resonator.

It is possible that the BAW resonator also comprises a number n of additional conductive layers between the bottom piezoelectric layer and the top piezoelectric layer. The resonator may then also comprise an additional piezoelectric layer between the bottom piezoelectric layer and the top piezoelectric layer, in such a manner that each conductive layer is separated from another conductive layer by at least one piezoelectric layer. n is a natural number greater than or equal to 1.

With more than one conductive layer between the electrodes, the formation and alignment of the electrical field in the border region of the resonator may be further improved in comparison with a resonator having only a single conductive layer plus the electrode layers.

It is possible that the conductive layer reduces an electrical field having a horizontal orientation in a border region of the resonator.

As described above, the material of the conductive layer aids in the formation of the shape and alignment of the field distribution in the border region of the resonator. It is preferred if horizontal components of the electrical field are eliminated or at least reduced.

It is possible that the overlap region of the bottom electrode, the piezoelectric layers and the top electrode determines the active region of the resonator as described above. Furthermore, the conductive layer possesses a homogeneous material composition and a homogeneous thickness within the active region. The homogeneity of the material composition and the thickness extend beyond the area of the resonator in order to increase the homogeneity and symmetry of the material, as considered regarding the sound waves propagating in the resonator.

It is possible that a thickness extensional wave mode propagates in the direction of the thickness of the resonator. The thickness extensional wave mode has a half wavelength λ/2, wherein λ/2 is primarily the distance between the bottom electrode and the top electrode. The conductive layer has a thickness between 0.1λ and 0.2λ, or between 0.2λ and 0.4λ, or between 0.01λ and 0.1λ, for example between 0.05λ and 0.1λ.

It is possible that the BAW resonator has a material of the piezoelectric layer that is chosen from LiTaO₃ (lithium tantalate), LiNbO₃ (lithium niobate), quartz, AlN (aluminum nitride), Sc-doped AlN (Scandium-doped aluminum nitride), PZT (lead zirconate titanate), ZnO (zinc oxide), or another piezoelectric material. In particular, for use in BAW resonators materials are preferred that may be deposited at a high crystallographic quality using thin film deposition techniques, for instance physical vapor deposition, for example sputtering, or chemical vapor deposition.

The material of the electrode layers may be chosen from Al (aluminum), Cu (copper), Ag (silver), Au (gold), W (tungsten), Ru (ruthenium), Mo (molybdenum), Ti (titanium), Ta (tantalum), or other metals or alloys that comprise at least one of these metals, for instance AlCu.

The material of the conductive layer, or of an additional conductive layer, may likewise be chosen from Al (aluminum), Cu (copper), Ag (silver), Au (gold), W (tungsten), Ru (ruthenium), Mo (molybdenum), Ti (titanium), Ta (tantalum), or other metals or alloys that comprise at least one of these metals, for instance AlCu.

It is possible that the BAW resonator has a clearance of bottom electrode and top electrode of 400 nm or greater and 600 nm or less.

The thickness of the material between the electrodes, and the sound velocity of the material between the electrodes, determine the frequency of the resonator. Conventional methods for calculating the frequency of the resonator or, for a given frequency, the thickness of the resonator are no longer valid in the event that an additional conductive layer is present that changes the propagation of sound waves in the resonator stack. Methods for calculation of the precise dimensions and thicknesses of the different layers thus must take into account the presence of the one or more conductive layers between the electrodes.

It is possible that the conductive layer has a thickness d greater than or equal to 50 nm, and less than or equal to 500 nm. A preferred thickness is between 60 and 200 nm.

It is possible that, in the event that the resonator comprises more than one conductive layer, the sum of the thicknesses of the individual conductive layers is between 50 nm and 200 nm.

It is possible that the resonator is an SMR-type resonator (SMR=Solidly Mounted Resonator) or a TFBAR-type resonator (TFBAR=Thin-Film Bulk Acoustic Resonator).

An SMR-type resonator has an acoustic mirror underneath the bottom electrode. The resonator stack thus contains the two electrodes, and the material between the electrodes, and additional layers with alternating high and low acoustic impedance under the bottom electrode. The acoustic mirror reflects sound waves so that the acoustic energy for an increased quality factor is limited to the layer system.

A TFBAR-type resonator has a cavity under the bottom electrode in such a manner that the acoustic energy is also limited to the resonator, in particular to the region of the electrodes and the interposed material. The resonator stack of a TFBAR-type resonator may be supported by a carrier that has a cutout that defines the cavity under the active region.

A corresponding BAW filter comprises two or more BAW resonators as described above and a common carrier. The resonators are arranged next to one another on the carrier. The resonators have a corresponding conductive layer at the same vertical position. The conductive layers are electrically separated from one another.

Manufacturing steps may be simplified via the arrangement of the electrically separated conductive layers of the various resonators at the same vertical position, since the material of the respective conductive layers may be deposited simultaneously. However, structuring steps are required in order to electrically separate the conductive layers of the various resonators from one another.

A method for producing a BAW resonator includes the steps:
generate a bottom electrode,
generate a bottom piezoelectric layer on the bottom electrode,
generate a conductive layer on the bottom piezoelectric layer,
generate a top piezoelectric layer on the conductive layer,
generate a top electrode on the top piezoelectric layer.

It is possible that a resonator having multiple conductive layers between the bottom electrode and the top electrode is built up via alternating generation of the additional conductive layers and additional piezoelectric layers between the bottom piezoelectric layer and the top piezoelectric layer.

Additional operating principles and illustrative embodiments are provided via the accompanying schematic drawings for a better comprehension.

Shown in the drawings are:

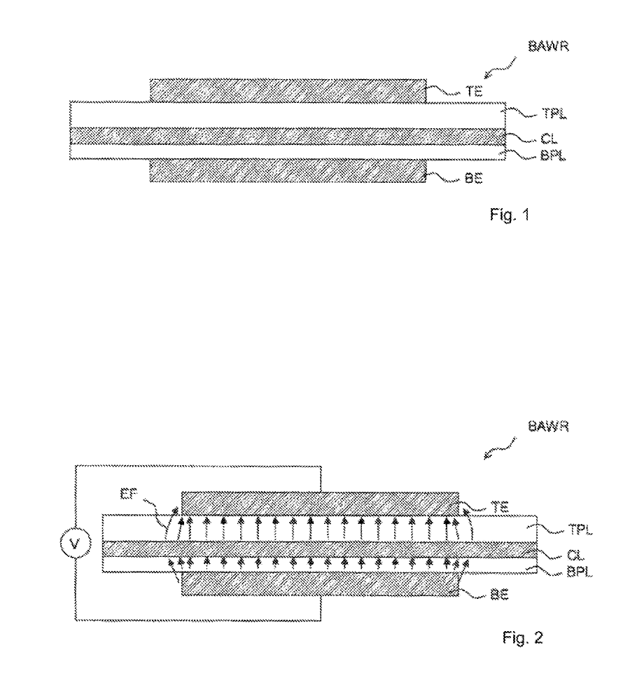

FIG. 1 the basic design of a BAW resonator,

FIG. 2 the effect of the conductive layer on the electrical field,

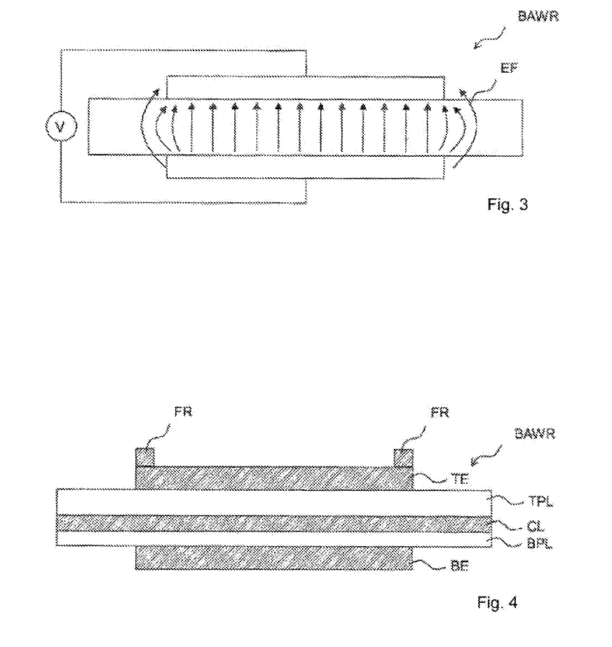

FIG. 3 the electrical field distribution of a conventional resonator,

FIG. 4 an embodiment having an additional frame structure on the top electrode,

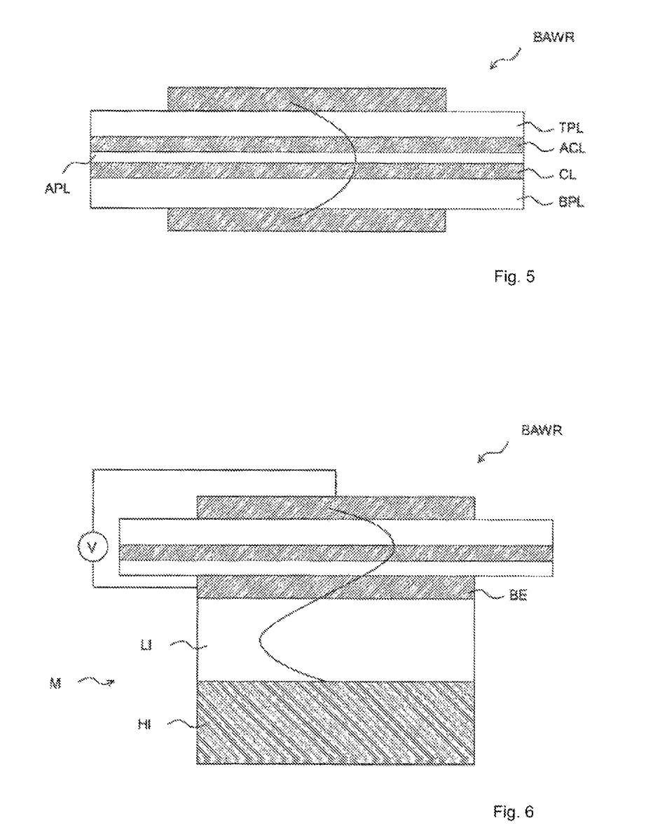

FIG. 5 an embodiment having two conductive layers between the electrodes,

FIG. 6 an embodiment realized as an SMR-type resonator,

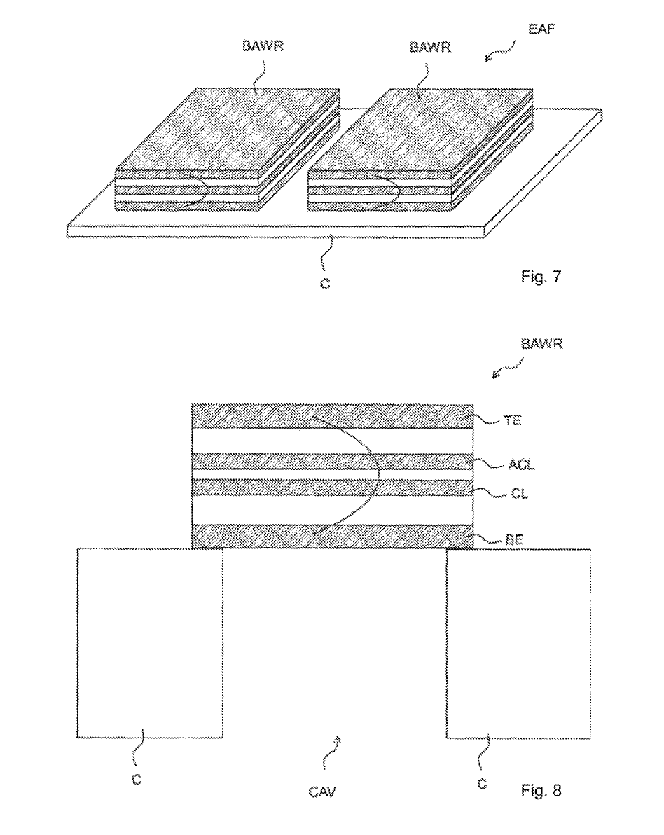

FIG. 7 an electroacoustic filter that comprises two BAW resonators on a common carrier,

FIG. 8 a TFBAR-type resonator.

FIG. 1 schematically shows a cross section of a BAW resonator BAWR that has a bottom electrode BE and a top electrode TE. Arranged between the bottom electrode BE and the top electrode TE is piezoelectric material in the form of a bottom piezoelectric layer BPL and a top piezoelectric layer a TPL. An additional conductive layer CL comprising a conductive material is inserted between the bottom electrode BE and the top electrode TE, in particular between the bottom piezoelectric layer BPL and the top piezoelectric layer TPL.

FIG. 2 shows the effect of the conductive layer CL on the electrical field illustrated by the arrows, in the event that an external HF signal is applied to the resonator BAWR. The bottom electrode and the top electrode designate the electrodes of a capacitor having a piezoelectric layer BPL, TPL as the dielectric that separates the electrodes of the capacitor. In the inner sections of the active region, the electrical field has a predominantly vertical alignment. The symmetry of the arrangement, and thus the symmetry of the electrical field, is disturbed in the border region of the resonator. In the border region of the resonator, the electrical field has an orientation that may deviate from the vertical direction. However, with the presence of the conductive layer CL [sic]—since the electrical field has an orientation orthogonal to a conductive layer in the event that the electrons in the conductive material have sufficient time to rearrange themselves. The horizontal alignment of the conductive layer CL thus aids in maintaining a vertical alignment of the electrical field, even in the border region of the resonator. This effect is intensified in the event that the material of the conductive layer CL extends beyond the active region of the resonator BAWR.

In contrast to this, FIG. 3 shows the electrical field distribution of a conventional BAW resonator BAWR in which the electrical field EF has much more strongly pronounced components with a horizontal orientation, which leads to the excitation of spurious modes.

FIG. 4 shows a cross section through an embodiment that has a frame FR arranged on the top electrode TE in order to improve the acoustics in the border region of the resonator. Since the conductive layer CL aids in decoupling electrical effects from acoustic effects in BAW resonators, the frame structure FR may more efficiently improve the acoustics of the resonator.

FIG. 5 shows a cross section of a BAW resonator BAWR that has two conductive layers, the conductive layer CL and the additional conductive layer ACL. An additional piezoelectric layer APL is thus also arranged between the conductive layer CL and the additional conductive layer ACL. A TE mode with a half wavelength λ/2 may propagate in the layer construction.

FIG. 6 schematically shows a resonator according to the aforementioned principles having a conductive layer that is designated as an SMR-type resonator. The resonator BAWR has an acoustic mirror M that comprises one layer having a lower acoustic impedance LI and one layer having a high acoustic impedance HI. The mirror M may comprise additional layers with alternating acoustic impedance, wherein the number of layers determines the quality factor since the mirror aids in limiting the acoustic energy, and it prevents the acoustic energy from dispersing.

FIG. 7 shows a schematic arrangement of an electroacoustic filter EAF that comprises two bulk acoustic wave resonators BAWR that are arranged next to one another on a common carrier C. Two or more resonators may be arranged and electrically connected in a conductor-like configuration with a series resonator that is arranged in series in a signal path, and shunt resonators that connect the signal path to ground. Depending on the precise configuration, such a conductor-like configuration may define a bandpass filter or a band-stop filter.

The electrodes and the conductive layers of various resonators must be electrically separated. However, the conventionally non-conductive piezoelectric materials of the two or more piezoelectric layers may extend continuously beyond the region of all resonators. Additional steps to structure the piezoelectric material are thus not necessary.

FIG. 8 schematically shows a TFBAR-type BAW resonator BAWR in which the acoustic energy is limited via arrangement of the sandwich construction over the cavity CAV. The layer construction may be supported in the border region by a carrier C in which the cavity is determined as a cutout or a hole.

### LIST OF REFERENCE SIGNS

ACL: additional conductive layer
APL: additional piezoelectric layer
BAWR: BAW resonator
BE: bottom electrode
BPL: bottom piezoelectric layer
C: Carrier
CAV: Cavity
CL: conductive layer
EAF: electroacoustic filter
EF: electrical field
FR: Frame
HI: layer having high acoustic impedance
LI: layer having low acoustic impedance
M: acoustic mirror
TE: top electrode
TPL: top piezoelectric layer
V: external HF signal (voltage)

1. A BAW resonator (BAWR) having reduced spurious modes, comprising
a bottom electrode (BE) and a top electrode (TE),
a bottom piezoelectric layer (BPL) that is arranged between the bottom electrode (BE) and the top electrode (TE),
a top piezoelectric layer (TPL) that is arranged between the bottom piezoelectric layer (BPL) and the top electrode (TE), and
a conductive layer (CL) that is arranged between the bottom piezoelectric layer (BPL) and the top piezoelectric layer (TPL), wherein
the conductive layer (CL) is electrically floating.

2. The BAW resonator of the preceding claim that also comprises n additional conductive layers (ACL) between the bottom piezoelectric layer (BPL) and the top piezoelectric layer (TPL), and n additional piezoelectric layers (APL) between the bottom piezoelectric layer (BPL) and the top piezoelectric layer (TPL), in such a manner that each conductive layer (ACL, CL) is separated from another conductive layer (ACL, CL) by at least one piezoelectric layer (APL, BPL, TPL), wherein n is a natural number ≥1.

3. The BAW resonator according to any of the preceding claims, wherein the conductive layer (CL) reduces an electrical field of a horizontal orientation in a border region of the resonator (BAWR).

4. The BAW resonator according to any of the preceding claims, wherein
the overlap region of the bottom electrode (BE), the piezoelectric layers (BPL, APL, TPL), and the top electrode (TE) determines the active region of the resonator, and
the conductive layer (CL) has a homogeneous material composition and homogeneous thickness within the active region.

5. The BAW resonator according to any of the preceding claims, wherein
a thickness extensional wave mode having a half wavelength λ/2 can propagate in a direction of the thickness of the resonator (BAWR), and
the conductive layer (CL) has a thickness between 0.01λ and 0.1λ.

6. The BAW resonator according to any of the preceding claims, wherein
the material of the piezoelectric layers (BPL, APL, TPL) is chosen from LiTaO₃, LiNbO₃, quartz, AlN, Sc-doped AlN, PZT, ZnO,
the material of the electrode layers (BE, TE) is chosen from Al, Cu, Ag, Au, W, Ru, Mo, Ti, Ta, an alloy having at least two of these metals, AlCu, and
the material of the conductive layer (CL, ACL) is chosen from Al, Cu, Ag, Au, W, Ru, Mo, Ti, Ta, an alloy having at least two of these metals, AlCu.

7. The BAW resonator according to any of the preceding claims with 50 nm≤d≤500 nm, wherein d is the thickness of the conductive layer (CL, ACL).

8. The BAW resonator according to any of the preceding claims, wherein the resonator (BAWR) is an SMR-type resonator or a TFBAR-type resonator.

9. The BAW filter, comprising
two or more BAW resonators (BAWR) according to any of the preceding claims and a carrier (C), wherein
the resonators (BAWR) are arranged next to one another on the carrier (C),
two resonators (BAWR) have a respective conductive layer (CL) at the same vertical position, and
the two conductive layers (CL) are electrically separated from one another.

10. A method for manufacturing a BAW resonator (BAWR) according to any of claims 1 through 6, including the steps:
generate a bottom electrode (BE),
generate a bottom piezoelectric layer (BPL) on the bottom electrode (BE),
generate a conductive layer (CL) on the bottom piezoelectric layer (BPL),
generate a top piezoelectric layer (TPL) on the conductive layer (CL),
generate a top electrode (TE) on the top piezoelectric layer (TPL).

11. The method according to the preceding claim, further including the step
alternating generation of additional conductive layers (ACL) and additional piezoelectric layers (APL) between the bottom piezoelectric layer (BPL) and the top piezoelectric layer (TPL).
